(19) United States
(12) Patent Application Publication
(10) Pub. No.: US 2026/0215065 A1
(43) Pub. Date: Jul. 23, 2026

(54) LEAD FRAME CUP FOR IMPROVED LIGHT EXTRACTION

(71) Applicant: CreeLED, Inc., Durham, NC (US)

(72) Inventors: Seth Joseph Balkey, Pittsboro, NC (US); Derek Miller, Columbus, OH (US)

(21) Appl. No.: 19/032,721

(22) Filed: Jan. 21, 2025

(51) Int. Cl. H10H 29/85

(52) U.S. Cl. CPC H10H 29/857

(57) ABSTRACT

Light-emitting diode (LED) devices and, more particularly, lead frame cups with curved side walls for improved light extraction in LED packages are disclosed. Exemplary lead frame structures with lead frame cups are provided with curved side walls that are designed to improve the light extraction over conventional straight walled lead frame cups. The curved side walls can either be parabolic side walls or round side walls that have a radius of curvature that approximate the parabolic side walls. The parabolic side walls can have the ideal shape in order to maximize light extraction, while the rounded side walls that define an arc of a circle can be easier to manufacture. The curvature of the side walls in both embodiments can be based on a distance of the edge of the LED chip within the LED package to the side wall, as well as a height of a midpoint of the LED chip.

### FIELD OF THE DISCLOSURE

The present disclosure relates to light-emitting diode (LED) devices, and more particularly to a lead frame cup with curved side walls for improved light extraction in LED packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs continue to enable a variety of new LED display and general illumination applications.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices and more particularly to lead frame cups with curved side walls for improved light extraction in LED packages. Exemplary lead frame structures with lead frame cups are provided with curved side walls that are designed to improve the light extraction over conventional straight walled lead frame cups. The curved side walls can either be parabolic side walls or round side walls that have a radius of curvature that approximate the parabolic side walls. The parabolic side walls can have the ideal shape in order to maximize light extraction, while the rounded side walls that define an arc of a circle can be easier to manufacture. The curvature of the side walls in both embodiments can be based on a distance of the edge of the LED chip within the LED package to the side wall, as well as a height of a midpoint of the LED chip.

In one aspect, an LED package includes a housing forming a recess with a recess floor, wherein the housing comprises curved side walls, a lead frame within the housing, a metal pad in the recess, the metal pad formed on only a portion of the lead frame, and an LED chip on the metal pad wherein an axis of symmetry of a curved side wall of the curved side walls is based on a position of the LED chip relative to the curved side wall. In an embodiment, the curved side walls are parabolic. In an embodiment, the axis of symmetry of the curved side wall is coincident with an edge of the LED chip closest to the curved side wall. In an embodiment, a focus of the curved side wall is on a side of the LED chip, halfway between a top and a bottom of the LED chip. In an embodiment, a vertex of the curved side wall is beneath the LED chip. In an embodiment, curved side walls define an arc of a circle. In an embodiment, the axis of a symmetry of a curved side wall of the curved side walls is between a center of the LED chip and an edge of the LED chip closest to the curved side wall. In an embodiment, the recess is a quadrilateral. In an embodiment, every curved side wall of the curved side walls has an equal curvature. In an embodiment a first side wall of the curved side walls has a first curvature, and a second side wall of the curved side walls has a second curvature different than the first curvature. In an embodiment, side wall corners of the curved side walls have a swept profile transitioning between adjacent curved side walls.

In another aspect, an LED package includes a housing forming a recess with a recess floor, wherein the housing comprises curved side walls that are parabolic, a lead frame within the housing, a metal pad in the recess, the metal pad formed on only a portion of the lead frame, and an LED chip on the metal pad wherein an axis of symmetry of a curved side wall of the curved side walls is coincident with an edge of the LED chip closest to the curved side wall. In an embodiment, a focus of the curved side wall is on a side of the LED chip, halfway between a top and a bottom of the LED chip. In an embodiment, a vertex of the curved side wall is beneath the LED chip. In an embodiment the recess is a quadrilateral. In an embodiment, every curved side wall of the curved side walls has an equal curvature. In an embodiment, a first side wall of the curved side walls has a first curvature, and a second side wall of the curved side walls has a second curvature different than the first curvature.

In another aspect, an LED package includes a housing forming a recess with a recess floor, wherein the housing comprises curved side walls that define an arc of a circle. The LED package also includes a lead frame within the housing, a metal pad in the recess, the metal pad formed on only a portion of the lead frame, and an LED chip on the metal pad wherein an axis of a symmetry of a curved side wall of the curved side walls is between a center of the LED chip and an edge of the LED chip closes to the curved side wall. In an embodiment, the recess is a quadrilateral and every curved side wall of the curved side walls has an equal curvature. In an embodiment, the recess is a quadrilateral and a first side wall of the curved side walls has a first curvature, and a second side wall of the curved side walls has a second curvature different than the first curvature.

In another aspect, A lighting device includes a board and a light-emitting diode (LED) package mounted on the board, where the LED package includes a housing forming a recess with a recess floor, wherein the housing comprises curved side walls, a lead frame within the housing, a metal pad in the recess, the metal pad formed on only a portion of the lead frame, and an LED chip on the metal pad wherein an axis of symmetry of a curved side wall of the curved side walls is based on a position of the LED chip relative to the curved side wall.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top down view of a first embodiment of a light-emitting diode (LED) package with a lead frame cup with curved side walls according to principles of the present disclosure.

FIG. 1B is a cross-sectional view of the LED package of FIG. 1A according to principles of the present disclosure.

FIG. 2A is a top down view of a second embodiment of a LED package with a lead frame cup with curved side walls according to principles of the present disclosure.

FIG. 2B is a cross-sectional view of the LED package of FIG. 2A according to principles of the present disclosure.

FIG. 3A is a cross-sectional view of the LED package of FIGS. 1A and 1B with parabolic side walls according to principles of the present disclosure.

FIG. 3B is a cross-sectional view of the LED package of FIGS. 1A and 1B with round side walls according to principles of the present disclosure.

FIG. 4A is a cross-sectional view of the LED package of FIGS. 2A and 2B with parabolic side walls according to principles of the present disclosure.

FIG. 4B is a cross-sectional view of the LED package of FIGS. 2A and 2B with round side walls according to principles of the present disclosure.

FIG. 5 is a ray trace diagram of an LED package with curved side walls according to principles of the present disclosure.

FIG. 6 is a schematic diagram of a portion of an LED device, such as a display screen including a large number of LED packages according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices and more particularly to lead frame cups with curved side walls for improved light extraction in LED packages. Exemplary lead frame structures with lead frame cups are provided with curved side walls that are designed to improve the light extraction over conventional straight walled lead frame cups. The curved side walls can either be parabolic side walls or round side walls that have a radius of curvature that approximate the parabolic side walls. The parabolic side walls can have the ideal shape in order to maximize light extraction, while the rounded side walls that define an arc of a circle can be easier to manufacture. The curvature of the side walls in both embodiments can be based on a distance of the edge of the LED chip within the LED package to the side wall, as well as a height of a midpoint of the LED chip.

Before delving into specific details of various aspects of the present disclosure, an overview of elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements.

The active LED structure can be fabricated from different material systems, with some material systems being Group III nitride-based material systems. Group III nitrides refer to semiconductor compounds formed between nitrogen (N) and elements in Group III of the periodic table, usually aluminum (Al), gallium (Ga), and/or indium (In) in the form of binary, ternary, and/or quaternary compounds. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure can emit different wavelengths of light depending on the composition of the active layer. In certain embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B light is typically defined as a peak wavelength range from 280 nm to 315 nm, and UV-C light is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

Aspects of the present disclosure are applicable to multiple-chip LED packages where multiple LED chips are arranged within a common recess and sometimes beneath a common lens of an LED package. For example, LED packages may include a red-emitting LED chip, a green-emitting LED chip, and a blue-emitting LED chip such that the LED package may be positioned as a pixel in an LED display. In other embodiments, aspects of the present disclosure may be applicable to other LED packages, such as those that include one or more LED chips with a recipient lumiphoric material that converts at least a portion of light generated from the one or more LED chips to a different wavelength.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphoric material receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a support structure of an LED package such that the anode and cathode connections are on a face of the LED chip that is opposite the support structure. In this configuration, wire bonds may be used to provide electrical connections with the anode and cathode connections. In other embodiments, a lateral geometry LED chip may be flip-chip mounted on a surface of a support structure of an LED package such that the anode and cathode connections are on a face of the active LED structure that is adjacent to the support structure. In this configuration, electrical traces or portions of a lead frame may be provided with the support structure for providing electrical connections to the anode and cathode connections of the LED chip. In a flip-chip configuration, the active LED structure is configured between the substrate of the LED chip and the support structure for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a lead frame structure or a submount. Lead frame structures are typically at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. In certain embodiments, one or more lumiphoric materials, such as phosphor particles, may be integrated or otherwise embedded within the encapsulant material.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Light-altering materials may be arranged within LED packages to reflect or otherwise redirect light from the one or more LED chips in a desired emission direction or pattern. Encapsulant materials may be formed to cover LED chips and portions of the submount and in certain embodiments, encapsulant materials may form lenses that direct light in desired emission directions and/or patterns.

Light-altering materials may be arranged within LED packages, such as within housings and/or within portions of recesses thereof, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

In conventional LED packages the lead frame cup formed by the housing is typically trapezoidal in volume, with a recess floor and then straight angled side walls that are angled so that the top of the recess is wider and longer than the recess floor. The recess floor is typically quadrilateral with straight edged corner sections. The LED chip placed in or near the center of the recess emits light including from the side of the LED chip towards the side walls. The angled side walls reflect the light generally out of the lead frame cup, with the angle depending on the angle of incidence. While the light is reflected out of the cup, the far field emission pattern, without lenses, or other optics, is wide, broad, and can be uneven.

To solve these problems, the LED package with a housing that forms a lead frame cup with curved side walls is disclosed in order to improve the light extraction efficiency and far field emission pattern. In some embodiments, parabolic side walls can be provided to maximize the improvements, while additionally rounded side walls with a focus and radius of curvature configured to approximate the parabolic side walls can achieve most of the benefits, while providing an easier to manufacture process.

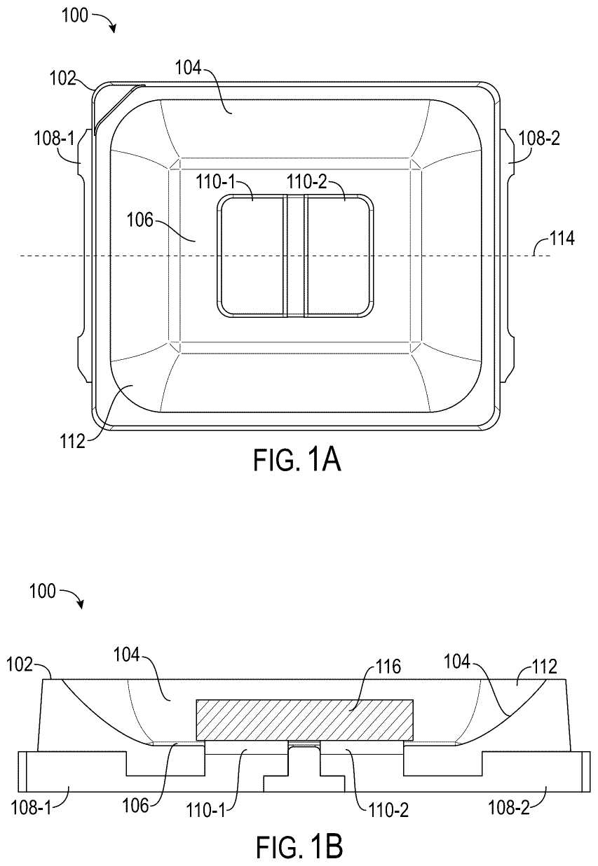

FIG. 1A is a top down view of a first embodiment of an exemplary LED package 100 with curved side walls according to principles of the present disclosure. FIG. 1B is a cross-sectional view of the LED package 100 of FIG. 1A taken along the sectional line 114 of FIG. 1A.

The LED package 100 includes a lead frame structure that collectively formed by a plurality of leads 108-1 and 108-2, and a body or housing 102 that encases a portion of the lead frame structure. The housing 102 forms a recess with a perimeter thereof defined by one or more curved side walls 104 and a recess floor 106 at a base of the recess. Within the recess, metal pads 110-1 and 110-2 collectively form a die attach area for an LED chip 116 that will be mounted thereon. The metal pads 110-1 and 110-2 are selectively plated on respective portions of the leads 108-1 and 108-2, thereby increasing a height of a mounting surface for the LED chip above the recess floor 106. In this regard, the metal pads 110-1 and 110-2 may form pedestals into the recess. The metal pads 110-1 and 110-2 may be selectively formed by various techniques, such as selective plating or hot air solder leveling.

The curved side walls 104 can be either parabolic or define arcs of a circle that approximate the parabolic shape in order to improve light extraction efficiency and far field emission patterns relative to traditional straight walled side walls in LED packages. In an embodiment, the curvature of the side walls 104 can be configured such that that light emitted by the LED chip 116 towards the side walls 104 is reflected out of the LED package in a more collimated manner. The curvature of the side walls 104 can be configured based on the position of the LED chip 116 such as the distance of an edge of the LED chip 116 from the curved side walls 104 and on a height of the LED chip 116 above the recess floor 106. The corner sections can also be curved, with the curvature sweeping around from the adjacent sides of the housing 102.

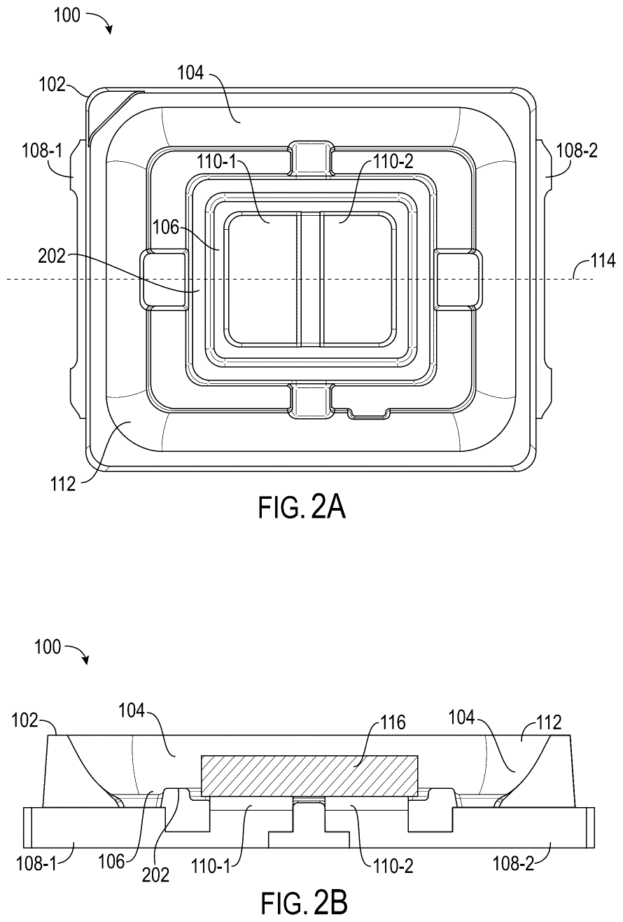

FIG. 2A is a top down view of a second embodiment of an exemplary LED package 100 with curved side walls according to principles of the present disclosure. FIG. 2B is a cross-sectional view of the LED package 100 of FIG. 2A taken along the sectional line 114 of FIG. 2A.

The embodiment of the LED package 100 in FIGS. 2A and 2B is an LED package that provides electrostatic discharge (ESD) protection for the LED chip 116 and includes a dam 202 that surrounds the LED chip 116 to serve as a buffer. In other respects, the embodiment in FIGS. 2A and 2B is similar to the embodiments in FIGS. 1A and 1B. The different embodiments are merely provided to show that the curved side walls can be implemented in a variety of styles of LED packages, including in other embodiments, ones with vertical geometry LED chips.

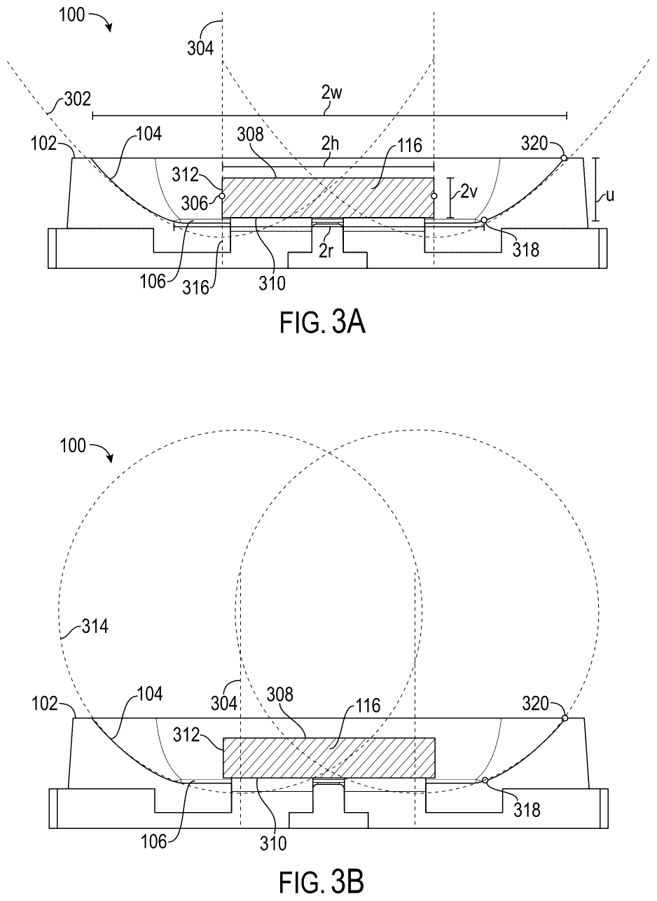

FIG. 3A is a cross-sectional view of the LED package of FIG. 1B with parabolic side walls according to principles of the present disclosure.

FIG. 3A shows the same cross-sectional view of the LED package 100 as in FIG. 1B, except with tracings showing the parabolic curved side walls 104. The curved side walls 104 are parabolic where the parabola 302 has a focus 306 that is on an outer edge 312 of the LED chip 116 that is closest to the curved side wall 104 and is half way between the top 308 of the LED chip 116 and the bottom 310 of the LED chip 116. The axis of symmetry 304 of the parabola 302 is therefore coincident with the edge 312 of the LED chip 116. Additionally, the vertex 316 of the parabola 302 is beneath the LED chip 116

In an embodiment, the standard form of parabola is provided by the equation 1 below:

$$y = \frac{{( x - h )}^{2}}{4 p} + k \qquad ( Equation 1 )$$

The focus 306 is defined as h, k+p, or (h, v), while the Vertex 316 is defined by h, k. Furthermore, a first point 318 where the recess floor 106 meets the sidewalls 104 is (r,0), while a second point 320 at the top of the curved sidewalls 104 is defined as (w,u).

The dimensions 2h, 2w, 2v, u, and 2r are shown in FIG. 3A.

The package optimized parabola as shown in FIG. 3A can be defined according to the following parabolic equation:

$$y = \frac{{u ( x - h )}^{2}}{{( w - h )}^{2} - {( r - h )}^{2}} - \frac{{( w - h )}^{2} - {( r - h )}^{2}}{4 u} + v \qquad ( Equation 2 )$$

where w>r>h, and:

$$v = k + p = \frac{{u ( x - h )}^{2}}{{( w - h )}^{2} - {( r - h )}^{2}} + \frac{{( w - h )}^{2} - {( r - h )}^{2}}{4 u} \qquad ( Equation 3 )$$

FIG. 3B is a cross-sectional view of the LED package of FIG. 1B but with round side walls that define the arc of a circle 314 instead of a parabola as in FIG. 3A.

The curved side walls 104 are formed such that the surface of the curved side walls 104 define an arc of a circle 314 that has a vertical axis of symmetry 304 that lies between the edge 312 of the LED chip 116 and a center of the LED chip 116, with the position dependent on the size of the LED chip 116, the size of the recess, height of the LED chip 116 above the recess floor 106, and distance of the edge 312 of the LED chip 116 from the curved side walls 104.

The corresponding radius of curvature to fit the parabolic segment can be found by calculating the instantaneous radius of curvature for any given point on the parabola and placing opposing ends of the arc section at point 318 and point 320.

The general parabolic radius of curvature is provided by Equation 4 below:

$$R = \frac{{[ 1 + {( \frac{dy}{dx} )}^{2} ]}^{3 / 2}}{\frac{{d}^{2} y}{{dx}^{2}}} \qquad ( Equation 4 )$$

The general arc segment of best fit is provided by the equation 5 below:

$$R = \frac{{[ 1 + {( - \frac{2 u ( x - h )}{( r - w ) ( - 2 h + r + w )} )}^{2} ]}^{3 / 2}}{( \frac{2 u}{{( w - h )}^{2} - {( r - h )}^{2}} )} \qquad ( Equation 5 )$$

Where r≤x≤w and the arc segment intersects at point 318 (r, 0) and point 320 (w, u).

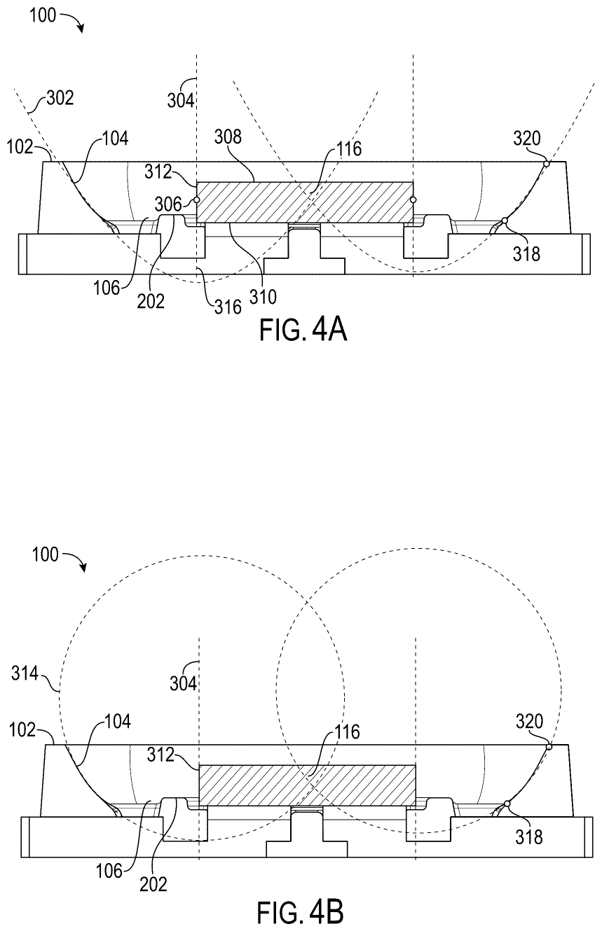

FIG. 4A shows the same cross-sectional view of the LED package 100 as in FIG. 2B, except with tracings showing the parabolic curved side walls 104. The curved side walls 104 are parabolic where the parabola 302 has a focus 306 that is on an outer edge 312 of the LED chip 116 that is closest to the curved side wall 104 and is half way between the top 308 of the LED chip 116 and the bottom 310 of the LED chip 116. The axis of symmetry 304 of the parabola 302 is therefore coincident with the edge 312 of the LED chip 116. Additionally, the vertex 316 of the parabola 302 is beneath the LED chip 116

FIG. 4B is a cross-sectional view of the LED package of FIG. 2B but with round side walls that define the arc of a circle 314 instead of a parabola as in FIG. 4A.

The curved side walls 104 are formed such that the surface of the curved side walls 104 define an arc of a circle 314 that has a vertical axis of symmetry 304 that lies between the edge 312 of the LED chip 116 and a center of the LED chip 116, with the position dependent on the size of the LED chip 116, the size of the recess, height of the LED chip 116 above the recess floor 106, and distance of the edge 312 of the LED chip 116 from the curved side walls 104.

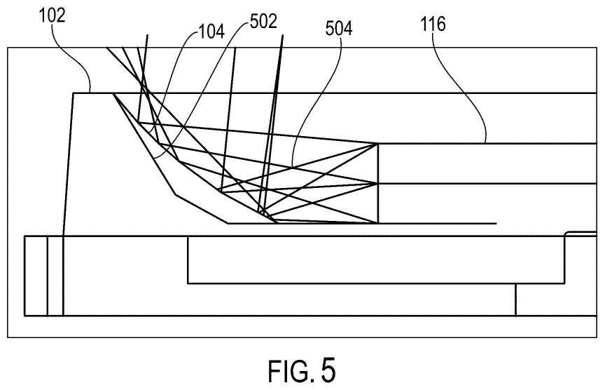

FIG. 5 is an exemplary ray trace diagram of an LED package with curved side walls 104 according to principles of the present disclosure. In FIG. 5, the light 504 emitted by the LED chip 116 from the top, bottom, and middle of the edge of the LED chip 116 is shown reflecting off of various portions of the surface of the curved side walls 104. The diagram also shows the curved side walls 104 in relation to the conventional straight side walls 502.

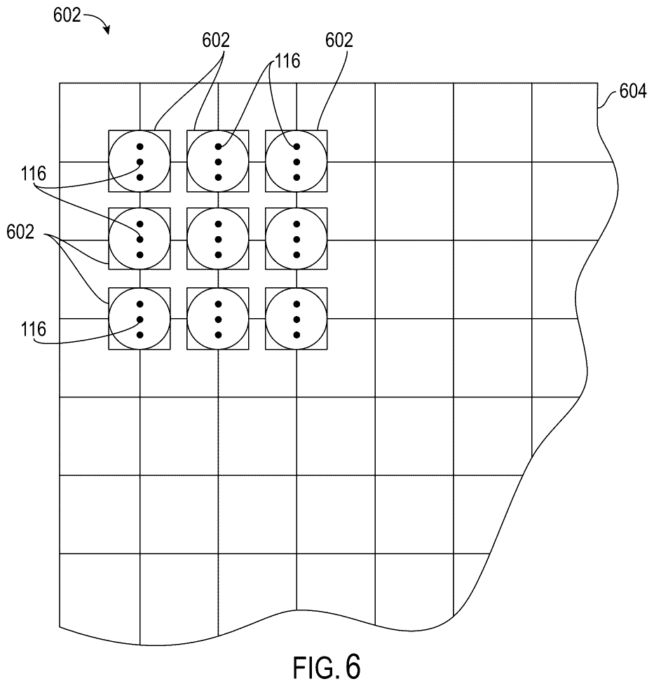

FIG. 6 is a schematic diagram of a portion of an LED device 600, such as a display screen, for example, an indoor and/or outdoor screen comprising, in general terms, a display panel including a driver printed circuit board (PCB) 604 carrying a large number of surface-mount devices (SMDs) 602 arranged in rows and columns, each SMD 602 defining a pixel. Additionally, each SMD 602 may represent a multiple chip embodiment of different colors, such as red-green-blue, for forming an LED pixel. The SMDs 602 are electrically connected to traces or pads on the PCB 604 to respond to appropriate electrical signal processing and driver circuitry (not shown). While FIG. 11 depicts the LED chips 116 in a linear arrangement within each LED package for the SMDs 602, in other embodiments, the LED chips 116 may be arranged in different configurations. The SMDs 602 can include the curved side walls 104 in their respective housings in order to improve light extraction efficiency and modify far field emission patterns.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package, comprising:
a housing forming a recess with a recess floor, wherein the housing comprises curved side walls;
a lead frame within the housing;
a metal pad in the recess, the metal pad formed on only a portion of the lead frame; and
an LED chip on the metal pad wherein an axis of symmetry of a curved side wall of the curved side walls is based on a position of the LED chip relative to the curved side wall.

2. The LED package of claim 1, wherein the curved side walls are parabolic.

3. The LED package of claim 2, wherein the axis of symmetry of the curved side wall is coincident with an edge of the LED chip closest to the curved side wall.

4. The LED package of claim 2, wherein a focus of the curved side wall is on a side of the LED chip, halfway between a top and a bottom of the LED chip.

5. The LED package of claim 2, wherein a vertex of the curved side wall is beneath the LED chip.

6. The LED package of claim 1, wherein the curved side walls define an arc of a circle.

7. The LED package of claim 6, wherein the axis of a symmetry of a curved side wall of the curved side walls is between a center of the LED chip and an edge of the LED chip closest to the curved side wall.

8. The LED package of claim 1, wherein the recess is a quadrilateral.

9. The LED package of claim 8, wherein every curved side wall of the curved side walls has an equal curvature.

10. The LED package of claim 8, wherein a first side wall of the curved side walls has a first curvature, and a second side wall of the curved side walls has a second curvature different than the first curvature.

11. The LED package of claim 1, wherein side wall corners of the curved side walls have a swept profile transitioning between adjacent curved side walls.

12. A light-emitting diode (LED) package, comprising:
a housing forming a recess with a recess floor, wherein the housing comprises curved side walls that are parabolic;
a lead frame within the housing;
a metal pad in the recess, the metal pad formed on only a portion of the lead frame; and
an LED chip on the metal pad wherein an axis of symmetry of a curved side wall of the curved side walls is coincident with an edge of the LED chip closest to a curved side wall.

13. The LED package of claim 12, wherein a focus of the curved side wall is on a side of the LED chip, halfway between a top and a bottom of the LED chip.

14. The LED package of claim 12, wherein a vertex of the curved side wall is beneath the LED chip.

15. The LED package of claim 12, wherein the recess is a quadrilateral.

16. The LED package of claim 15, wherein every curved side wall of the curved side walls has an equal curvature.

17. The LED package of claim 15, wherein a first side wall of the curved side walls has a first curvature, and a second side wall of the curved side walls has a second curvature different than the first curvature.

18. A light-emitting diode (LED) package, comprising:
a housing forming a recess with a recess floor, wherein the housing comprises curved side walls that define an arc of a circle;
a lead frame within the housing;
a metal pad in the recess, the metal pad formed on only a portion of the lead frame; and
an LED chip on the metal pad wherein an axis of a symmetry of a curved side wall of the curved side walls is between a center of the LED chip and an edge of the LED chip closest to a curved side wall.

19. The LED package of claim 12, wherein the recess is a quadrilateral and every curved side wall of the curved side walls has an equal curvature.

20. A lighting device comprising:
a board; and
a light-emitting diode (LED) package mounted on the board, the LED package comprising:
a housing forming a recess with a recess floor, wherein the housing comprises curved side walls;
a lead frame within the housing;
a metal pad in the recess, the metal pad formed on only a portion of the lead frame; and
an LED chip on the metal pad wherein an axis of symmetry of a curved side wall of the curved side walls is based on a position of the LED chip relative to the curved side walls.
